(19) United States
(12) Patent Application Publication
(10) Pub. No.: US 2012/0085988 A1
(43) Pub. Date: Apr. 12, 2012

(54) LIGHT-EMITTING DIODE DEVICE AND MANUFACTURING METHOD THEREOF

(76) Inventors: Kuo-Hui Yu, Tainan City (TW); Jing-Hong Li, Tainan City (TW); Chang-Hsin Chu, Tainan City (TW)

(21) Appl. No.: 13/037,737

(22) Filed: Mar. 1, 2011

(30) Foreign Application Priority Data
Oct. 6, 2010 (TW) 099134108

(51) Int. Cl. H01L 33/06; H01L 33/46

(52) U.S. Cl. 257/13; 438/29; 257/E33.008; 257/E33.068

(57) ABSTRACT

A light-emitting diode (LED) device includes a substrate, an epitaxial layer, a first electrode and a second electrode. The epitaxial layer is disposed on the substrate. The first electrode is disposed to the epitaxial layer and the second electrode is disposed on the epitaxial layer, and a first conductive finger of the second electrode and a first conductive finger of the first electrode are overlapped. Because the first conductive finger of the second electrode and the first conductive finger of the first electrode are overlapped, the light-emitting area of the LED device can be increased and the light shielded by the electrodes can be decreased significantly. Besides, overlapped electrodes can form a capacitor which can store electric charges to enhance the antistatic ability of the LED device.

### CROSS REFERENCE TO RELATED APPLICATIONS

This Non-provisional application claims priority under 35 U.S.C. §119(a) on Patent Application No(s). 099134108 filed in Republic of China on Oct. 6, 2010, the entire contents of which are hereby incorporated by reference.

### BACKGROUND OF THE INVENTION

1. Field of Invention

The invention relates to a light-emitting diode device and a manufacturing method thereof.

2. Related Art

Light-emitting diodes (LED) are made of semiconductor materials and are luminescence devices. LEDs have advantages of less power consumption, long lifespan, and fast response, and can be easily manufactured to a small device or an array, so they have been widely applied to various appliances, such as indicators of the computer and the household appliance, backlights of the LCD apparatus, traffic lights and vehicle lights.

FIG. 1 is a top view of a conventional LED device 1, and FIG. 2 is a sectional diagram of the LED device 1 taken along the section A-A in FIG. 1. As shown in FIGS. 1 and 2, the LED device 1 includes a substrate 11, an N type semiconductor layer 12, a multiple quantum well (MQW) layer 13, a P type semiconductor layer 14, a transparent conductive layer 15, a first electrode 16 and a second electrode 17. The first electrode 16 includes a conductive pad 161 and a conductive finger 162, and the second electrode 17 includes a conductive pad 171 and two conductive fingers 172. The conductive pads 161 and 171 can be wire-bonded to receive driving signals. The conductive fingers 162 and 172 are respectively disposed on the N type semiconductor layer 12 and the transparent conductive layer 15. Accordingly, the driving signal can drive the LED device 1 to emit light.

As described above, the conductive finger 162 of the first electrode 16 and the conductive fingers 172 of the second electrode 17 are staggered vertically. However, the staggered electrodes not only cause the subtraction of the light-emitting area of the LED device, but also shield a part of the light of the LED device, so that the light-emitting efficiency of the LED device is lowered down.

Therefore, it is an important subject to provide a light-emitting diode device with a novel configuration of the electrodes to increase the light-emitting area and decrease the light shielded by the electrodes.

### SUMMARY OF THE INVENTION

In view of the foregoing subject, an objective of the invention is to provide a light-emitting diode device with a novel configuration of the electrodes to increase the light-emitting area and decrease the light shielded by the electrodes and thus further to enhance the light-emitting efficiency.

To achieve the above objective, a light-emitting diode device according to the invention includes a substrate, an epitaxial layer, a first electrode and a second electrode. The epitaxial layer is disposed on the substrate. The first electrode is disposed to the epitaxial layer. The second electrode is disposed on the epitaxial layer. A first conductive finger of the second electrode and a first conductive finger of the first electrode are overlapped.

In one embodiment, the first conductive fingers of the first and second electrodes are strip-shaped. The conductive fingers can diffuse the current uniformly.

In one embodiment, the first electrode further includes a connection portion connecting to the first conductive finger of the first electrode. The second electrode further includes a connection portion connecting to the first conductive finger of the second electrode. The connection portions are not overlapped. The connection portions can be pad-shaped, and for example, they are conductive pads for wire-bonding.

In one embodiment, the first conductive finger of the first conductive electrode is disposed in a depression of the epitaxial layer, and can be covered by a reflective layer. Due to the reflective layer, the light-emitting direction of the LED device can be adjusted to prevent the electrodes from shielding the emitted light to enhance the light-emitting efficiency.

In one embodiment, the epitaxial layer includes a first semiconductor layer, a second semiconductor layer and a multiple quantum well (MQW) layer disposed between the first semiconductor layer and the second semiconductor layer, and the first electrode is disposed at the surface of the depression of the second semiconductor layer.

In one embodiment, an insulating layer is disposed between the first conductive finger of the first electrode and the first conductive finger of the second electrode. Due to the insulating layer, the first conductive finger of the first electrode and the first conductive finger of the second electrode are separated and form a parallel capacitor which can store electric charges to enhance the antistatic ability of the LED device.

In one embodiment, the first electrode further includes second conductive finger, the second electrode further includes a second conductive finger, and the second conductive fingers of the first and second electrodes are overlapped. The first conductive finger of the first electrode and the second conductive finger of the first electrode can be disposed in parallel. The first conductive finger of the second electrode and the second conductive finger of the second electrode can be disposed in parallel. Because the first conductive fingers of the first and second electrodes are overlapped and the second conductive fingers of the first and second electrodes are overlapped as well, the total overlapping area is increased, so that the light shielded by the electrodes can be reduced and the capacitance formed by the electrodes is increased to enhance the antistatic ability.

To achieve the above objective, a manufacturing method of a light-emitting diode device according to the invention comprises forming an epitaxial layer on a substrate; forming a first conductive finger of a first electrode at the epitaxial layer; and forming a first conductive finger of a second electrode on the epitaxial layer, so that the first conductive finger of the first electrode and the first conductive finger of the second electrode are overlapped.

In one embodiment, the manufacturing method further includes forming a reflective layer to cover the first conductive finger of the first electrode. Due to the reflective layer, the light-emitting direction of the LED device can be adjusted to prevent the electrodes from shielding the emitted light to enhance the light-emitting efficiency.

In one embodiment, the manufacturing method further includes forming an insulating layer between the first conductive finger of the first electrode and the first conductive finger of the second electrode. The insulating layer can be disposed in the depression. By the arrangement of the insulating layer, the first conductive finger of the first electrode and the first conductive finger of the second electrode are separated and form a parallel capacitor which can store electric charges to enhance the antistatic ability of the LED device.

In one embodiment, the manufacturing method further includes forming a second conductive finger of the first electrode; and forming a second conductive finger of the second electrode, so that the second conductive fingers of the first and second electrodes are overlapped. Because the first conductive fingers of the first and second electrodes are overlapped and the second conductive fingers of the first and second electrodes are overlapped as well, the total overlapping area is increased, so that the light shielded by the electrodes can be reduced and the capacitance formed is increased to enhance the antistatic ability.

As mentioned above, according to the LED device and the manufacturing method thereof of the invention, the first conductive fingers of the first and second electrodes are overlapped, so the area occupied by the electrodes is decreased in comparison with the staggered electrodes, so that the light-emitting area of the device is increased and the light shielded by the electrodes is decreased. Furthermore, the overlapped electrodes can form a capacitor that can store the electric chargers to enhance the antistatic ability of the device and thus to enhance the light-emitting efficiency and the performance of the device.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a top view of a conventional LED device;

FIG. 2 is a sectional diagram of the LED device taken along the section A-A in FIG. 1;

FIG. 3 is a top view schematically showing a light-emitting diode device of a preferred embodiment of the invention;

FIG. 4 is a sectional diagram of the LED device taken along the section A-A in FIG. 3;

FIG. 5 is a flow chart of a manufacturing method of an LED device of a preferred embodiment of the invention; and

FIGS. 6A to 6D are schematic diagrams demonstrating a manufacturing method of an LED device of a preferred embodiment of the invention.

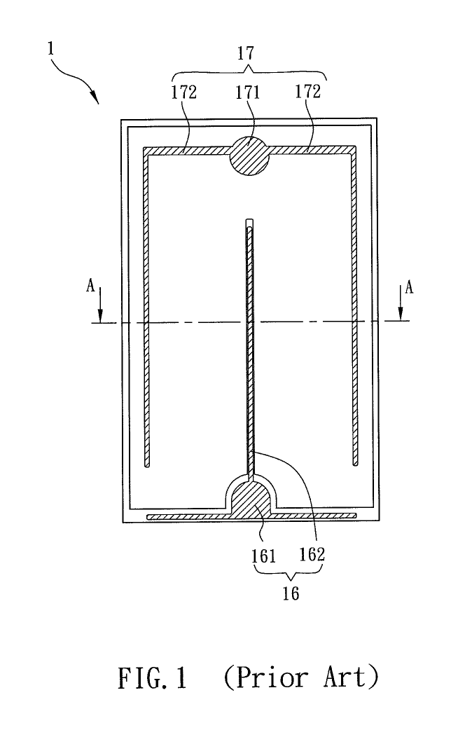

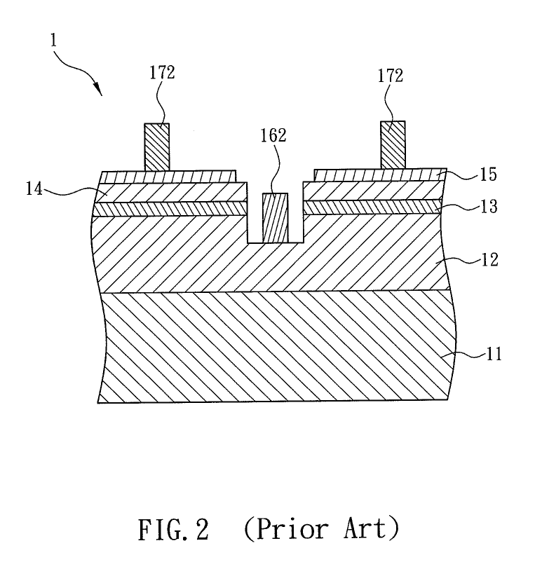

### DETAILED DESCRIPTION OF THE INVENTION

The present invention will be apparent from the following detailed description, which proceeds with reference to the accompanying drawings, wherein the same references relate to the same elements.

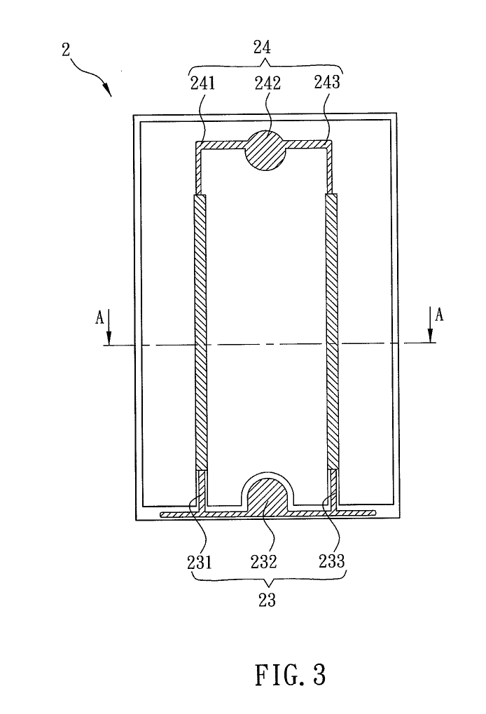

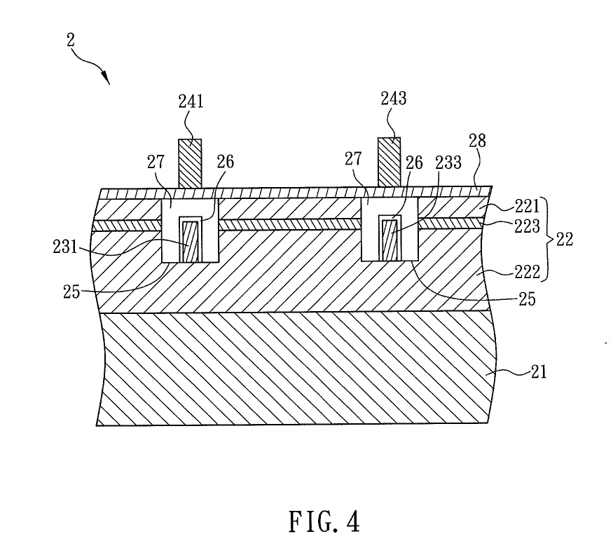

FIG. 3 is a top view of a light-emitting diode (LED) device 2 of a preferred embodiment of the invention, and FIG. 4 is a sectional diagram of the LED device 2 taken along the section A-A in FIG. 3. As shown in FIGS. 3 and 4, the LED device 2 includes a substrate 21, an epitaxial layer 22, a first electrode 23 and a second electrode 24.

The material of the substrate 21 can include, for example, sapphire, SiC, GaP or Si. Here, the material of the substrate 21 is sapphire for example.

The epitaxial layer 22 is disposed on the substrate 21. The epitaxial layer 22 is a semiconductor layer, for example including a first semiconductor layer 221 and a second semiconductor layer 222 that are different electric types. In the embodiment, the first semiconductor layer 221 is P type, and the second semiconductor layer 222 is N type. Besides, the material of the epitaxial layer 22 can be varied according to the types of the LED device, such as blue LED, green LED or red LED. The material of the epitaxial layer 22 can be selected from the group of GaN base semiconductors, such as InGaN, AlGaN or the group of AlInGaP base semiconductors. Besides, the epitaxial layer 22 can further include a multiple quantum well (MQW) layer 223 to generate the required color of light. The MQW layer 223 is disposed between the first and second semiconductor layers 221 and 222.

For electric connection of the second semiconductor layer 222, a portion of the first semiconductor layer 221 and the MQW layer 223 is removed by photolithography process for example to expose a surface of the second semiconductor layer 222, and the first electrode 23 is disposed on the exposed surface of the second semiconductor layer 222. The first electrode 223 includes the first conductive finger 231, the second conductive finger 233 and the connection portion 232. The first conductive finger 231 and the second conductive finger 233 are strip-shaped for example, for uniformly diffusing the current. The connection portion 232 is connected with the first conductive finger 231 and the second conductive finger 233 to form a conductive path thereby. The conductive portion 232 is, for example, a conductive pad for wire bonding.

The LED device 2 can further include a transparent conductive layer (TCL) 28, which is disposed on the epitaxial layer 22 to diffuse the current so that the uniformly distributed current can pass through the first semiconductor layer 221 and then the MQW layer 223. The material of the TCL 28 of the embodiment can include ITO for example.

The second electrode 24 is disposed on the TCL 28, and includes a first conductive finger 241, a second conductive finger 243 and a connection portion 242. The first conductive finger 241 and the second conductive finger 243 are strip-shaped for example, for uniformly diffusing the current. The connection portion 242 is connected with the first conductive finger 241 and the second conductive finger 243 to form a conductive path thereby. The connection portion 242 is, for example, a conductive pad for wire bonding.

As shown in FIG. 4, the first conductive finger 231 and the second conductive finger 233 of the first electrode 23 are disposed in a depression 25 that is formed by removing a portion of the epitaxial layer 22. The first conductive finger 231 and the second conductive finger 233 of the first electrode 23 are partially or totally covered by a reflective layer 26. Due to the reflective layer 26, the light-emitting direction of the LED device 2 can be adjusted to prevent the light from being shielded by the electrodes 23 and 24 and thus to enhance the light-emitting efficiency. The reflective layer 26 can be a film made of reflective metals, or made up of reflective structures. The reflective layer 26 can include transparent dielectric material. For example, the reflective layer 26 can include the reflective metal, such as Al, Ag, Pt or their alloy. Alternatively, the reflective layer 26 can include Distributed Bragg Reflector (DBR) and can be made of TiO₂, SiO₂ or SiN. Alternatively, the reflective layer 26 can be made of metal like Al, Ag or Pt and transparent dielectric material like TiO₂, SiO₂ or SiN.

Besides, an insulating layer 27 is disposed between the first conductive finger 231 of the first electrode 23 and the first conductive finger 241 of the second electrode 24. In the embodiment, the insulating layer 27 is disposed in the depression 25, and the first conductive finger 241 and the second conductive finger 243 of the second electrode 24 are disposed on the insulating layer 27. Furthermore, the first conductive finger 231 of the first electrode 23 and the first conductive finger 241 of the second electrode 24 are overlapped, the second conductive finger 233 of the first electrode 23 and the second conductive finger 243 of the second electrode 24 are overlapped, and the two electrodes 23 and 24 are separated by the insulating layer 27 physically and electrically. In other embodiments, the insulating layer 27 can be extended to cover a portion of the first semiconductor layer 221. By the insulating layer 27, the first conductive finger 231 of the first electrode 23 and the first conductive finger 241 of the second electrode 24 form a parallel capacitor, and the second conductive finger 233 of the first electrode 23 and the second conductive finger 243 of the second electrode 24 form another parallel capacitor. The capacitors can store electric chargers to enhance the antistatic ability of the LED device 2. Additionally, the insulating layer 27 can also act as current blocking layer (CBL), so that the current can be prevented from being flowed directly between the conductive fingers of the first electrode 23 and the second electrode 24. Accordingly, the current can be diffused uniformly so that the light-emitting area is increased and the light-emitting efficiency is enhanced.

The insulating layer 27 of the embodiment is a transparent insulating layer, which can include transparent material, such as SiO₂, SiN, TiO₂, Al₂O₃ or silicon on glass (SOG). Alternatively, the insulating layer 27 can include high dielectric coefficient material, such as HfSiON, HfO₂ or ZrO₂.

Because the first conductive fingers 231 and 241 of the first and second electrodes 23 and 24 are overlapped and the second conductive fingers 233 and 243 of the first and second electrodes 23 and 24 are overlapped, the area of the electrodes shielding the light is reduced and the effective light-emitting area is thus increased. Besides, the capacitance is increased to enhance the antistatic ability of the device. In the embodiment, the second conductive fingers 233 and 243 are connected with the connection portions 232 and 242 respectively. In other embodiments, the second conductive fingers 233 and 243 can be connected with another connection portion of the first electrode 23 and the second electrode 24 respectively. Besides, in the embodiment, the two connection portions 232 and 242 of the electrodes are not overlapped.

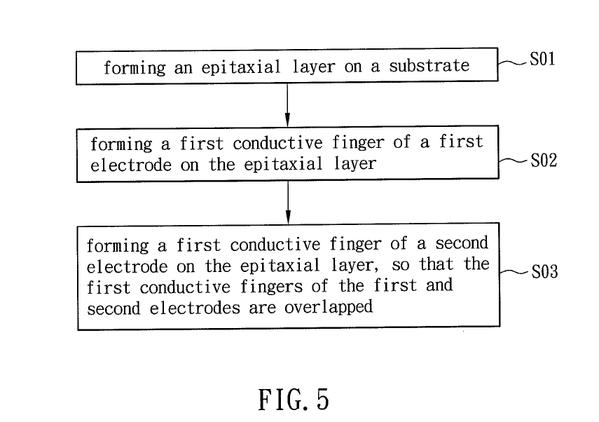

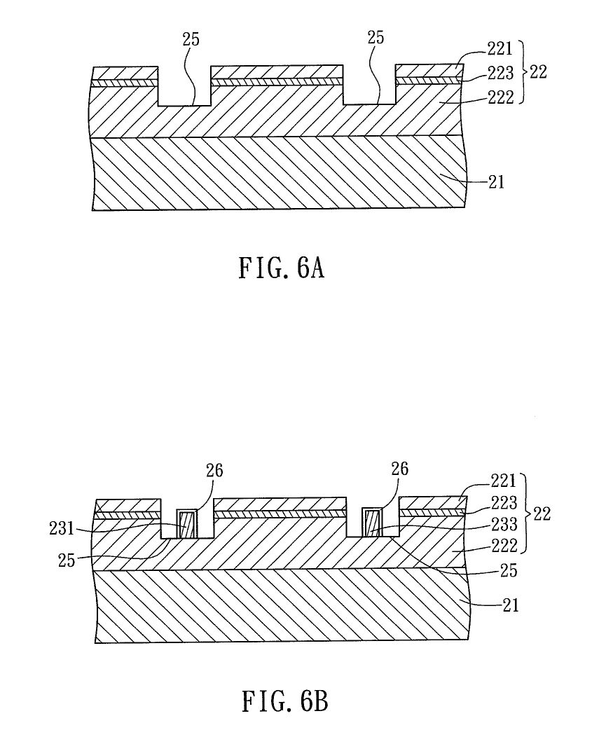

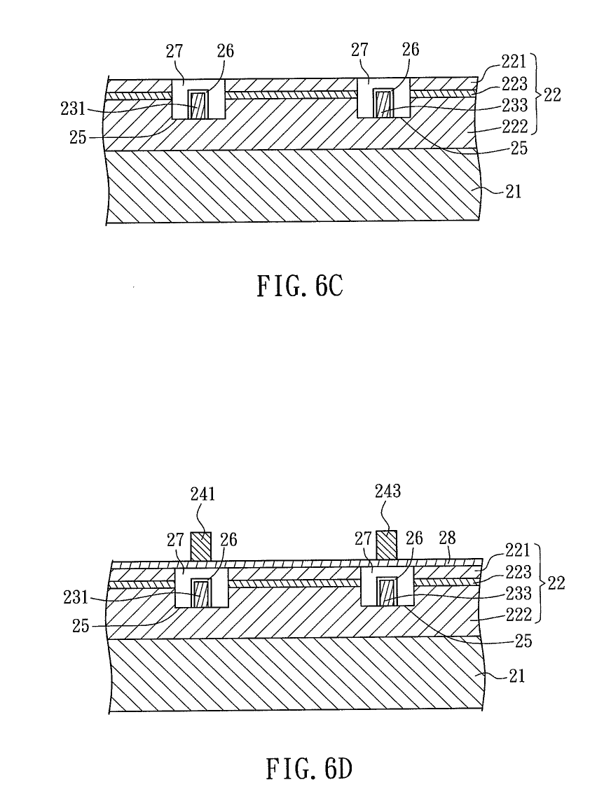

A manufacturing method of the LED device 2 is illustrated by FIG. 5 and FIGS. 6A to 6D. FIG. 5 is a flow chart of the manufacturing method, which includes the steps S01 to S03, and FIGS. 6A to 6D are schematic diagrams demonstrating the manufacturing method.

As shown in FIG. 6A, first, an epitaxial layer 22 is formed on a substrate 21 (the step S01) by MOCVD (metalorganic chemical vapor deposition) for example. The epitaxial layer 22 can include, for example, a first semiconductor layer 221, a second semiconductor layer 222 and a multiple quantum well layer 223. The first semiconductor layer 221 and the second semiconductor layer 222 are different electric types, and for example, the first semiconductor layer 221 is P type and the second semiconductor layer 222 is N type. The MQW layer 223 is disposed between the first semiconductor layer 221 and the second semiconductor layer 222. For electric connection of the second semiconductor layer 222, a portion of the first semiconductor layer 221 and the MQW layer 223 is removed by photolithography process for example, to expose a surface of the second semiconductor layer 222. The manufacturing method of the embodiment further includes etching the epitaxial layer 22 to form a depression 25. The epitaxial layer 22 of the embodiment is etched to the second semiconductor layer 222 to form the depression 225.

Then, a metal is formed on the epitaxial layer 22 by EBE (electron beam evaporation) and photolithography lift-off processes to form a first electrode 23. As shown in FIG. 6B, a first conductive finger 231 and a second conductive finger 233 of a first electrode 23 are formed on the epitaxial layer 22 (the step S02). The first conductive finger 231 and the second conductive finger 233 of the first electrode 23 are formed in the depression 25 and on the surface of the depression 25, contacting the second semiconductor layer 222. Of course, in the step of forming the first conductive finger 231, a connection portion 232 of the first electrode 23 also can be formed simultaneously, and the connection portion 232 is connected with the first and second conductive fingers 231 and 233 (as shown in FIG. 3). Besides, the manufacturing method further includes forming a reflective layer 26 that covers the first conductive finger 231 of the first electrode 23. In the embodiment, the reflective layer 26 also covers the second conductive finger 233 of the first electrode 23.

Next, as shown in FIG. 6C, the manufacturing method further includes forming an insulating layer 27 between the first conductive finger 231 of the first electrode 23 and the first conductive finger 241 of the second electrode 24. In the embodiment, an insulating material is formed on the entire surface of a side of the LED device 2 by CVD (Chemical vapor deposition) for example, and then, the unnecessary portion of the insulating material is removed by photolithograph process to form the insulating layer 27 that covers the first and second conductive fingers 231 and 233 of the first electrode 23. In the embodiment, the insulating layer 27 is formed in the depression 25.

Then, as shown in FIG. 6D, the manufacturing method further includes forming a transparent conductive material on the entire surface of the epitaxial layer 22 by EBE and then removing the unnecessary portion of the transparent conductive material by photolithography process to form a transparent conductive layer 28 on the epitaxial layer 22. Furthermore, a second electrode 24 is formed by forming a metal material on the transparent conductive layer 28 and then implementing photolithography lift-off process to the metal material. The manufacturing method further includes forming a first conductive finger 241 and a second conductive finger 243 of the second electrode 24, so that the first conductive finger 241 and the second conductive finger 243 of the second electrode 24 are overlapped with the first conductive finger 231 and the second conductive finger 233 of the first electrode 23 respectively (the step S03). Besides, the insulating layer 27 is disposed between the first and second conductive fingers 231 and 233 of the first electrode 23 and the first and second conductive fingers 241 and 243 of the second electrode 24. Of course, in the step of forming the first conductive finger 241, a connection portion 242 of the second electrode 24 can be also formed simultaneously and the connection portion 242 is connected with the first and second conductive fingers 241 and 243. The connection portion 232 of the first electrode 23 is not overlapped with the connection portion 242 of the second electrode 24, but the second conductive finger 233 of the first electrode 23 is overlapped with the second conductive finger 243 of the second electrode 24.

Because the features of the components revealed in the manufacturing method are illustrated clearly as the above embodiments, the detailed descriptions thereof are omitted.

In summary, according to the LED device and the manufacturing method thereof of the invention, the first conductive fingers of the first and second electrodes are overlapped, so the area occupied by the electrodes is decreased in comparison with the staggered electrodes, so that the light-emitting area of the device is increased and the light shielded by the electrodes is decreased. Furthermore, the overlapped electrodes can form a capacitor that can store the electric chargers to enhance the antistatic ability of the device and thus to enhance the light-emitting efficiency and the performance of the device.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting diode device, comprising:
a substrate;
an epitaxial layer disposed on the substrate;
a first electrode disposed to the epitaxial layer and having a first conductive finger; and
a second electrode disposed on the epitaxial layer, wherein a first conductive finger of the second electrode and the first conductive finger of the first electrode are overlapped.

2. The light-emitting diode device as recited in claim 1, wherein the first conductive fingers of the first electrode and the second electrode are strip-shaped.

3. The light-emitting diode device as recited in claim 1, wherein the first electrode further includes a connection portion connecting to the first conductive finger of the first electrode, the second electrode further includes a connection portion connecting to the first conductive finger of the second electrode, and the connection portions are not overlapped.

4. The light-emitting diode device as recited in claim 3, wherein the connection portions are conductive pads.

5. The light-emitting diode device as recited in claim 1, wherein the first conductive finger of the first conductive electrode is disposed in a depression of the epitaxial layer.

6. The light-emitting diode device as recited in claim 5, wherein the epitaxial layer includes a first semiconductor layer, a second semiconductor layer and a multiple quantum well (MQW) layer disposed between the first semiconductor layer and the second semiconductor layer, and the first electrode is disposed at the surface of the depression of the second semiconductor layer.

7. The light-emitting diode device as recited in claim 1, wherein the first conductive finger of the first electrode is covered by a reflective layer.

8. The light-emitting diode device as recited in claim 7, wherein the reflective layer is a film made of reflective metals, or made up of reflective structures, or includes transparent dielectric material.

9. The light-emitting diode device as recited in claim 5, further comprising:
an insulating layer disposed between the first conductive finger of the first electrode and the first conductive finger of the second electrode.

10. The light-emitting diode device as recited in claim 9, wherein the insulating layer acts as current blocking layer, so that the current can be prevented from being flowed directly between the first conductive fingers of the first electrode and the second electrode.

11. The light-emitting diode device as recited in claim 1, wherein the first conductive finger of the first electrode and the first conductive finger of the second electrode form a capacitor.

12. The light-emitting diode device as recited in claim 1, wherein the first electrode further includes a second conductive finger, the second electrode further includes a second conductive finger, and the second conductive fingers are overlapped.

13. A manufacturing method of a light-emitting diode device, comprising steps of:
forming an epitaxial layer on a substrate;
forming a first conductive finger of a first electrode at the epitaxial layer; and
forming a first conductive finger of a second electrode on the epitaxial layer, so that the first conductive finger of the first electrode and the first conductive finger of the second electrode are overlapped.

14. The manufacturing method as recited in claim 13, further comprising a step of:
etching the epitaxial layer to form a depression, so that the first conductive finger of the first electrode is disposed in the depression.

15. The manufacturing method as recited in claim 14, wherein the epitaxial layer includes a first semiconductor layer and a second semiconductor layer, and the step of etching the epitaxial layer to form the depression is to etch the epitaxial layer to the second semiconductor layer so that the first conductive finger of the first electrode is electrically connected with the second semiconductor layer.

16. The manufacturing method as recited in claim 13, further comprising a step of:
forming a reflective layer to cover the first conductive finger of the first electrode.

17. The manufacturing method as recited in claim 16, wherein the reflective layer is a layer made of reflective metals, or made up of reflective structures, or includes transparent dielectric material.

18. The manufacturing method as recited in claim 13, further comprising a step of:
forming an insulating layer between the first conductive finger of the first electrode and the first conductive finger of the second electrode.

19. The manufacturing method as recited in claim 13, further comprising steps of:
forming a connection portion of the first electrode to connect to the first conductive finger of the first electrode; and
forming a connection portion of the second electrode to connect to the first conductive finger of the second electrode; and
wherein the connection portions of the first and second electrodes are not overlapped.

20. The manufacturing method as recited in claim 13, further comprising steps of:
forming a second conductive finger of the first electrode at the epitaxial layer; and
forming a second conductive finger of the second electrode on the epitaxial layer, so that the second conductive fingers of the first and second electrodes are overlapped.
